(19) United States
(12) Patent Application Publication
(10) Pub. No.: US 2024/0297086 A1
(43) Pub. Date: Sep. 5, 2024

(54) INTERCONNECTION STRUCTURE AND PACKAGE STRUCTURE

(71) Applicant: Advanced Semiconductor Engineering, Inc., Kaohsiung (TW)

(72) Inventors: Chun-Wei CHIANG, Kaohsiung (TW); Yun-Ching HUNG, Kaohsiung (TW); Yung-Sheng LIN, Kaohsiung (TW)

(73) Assignee: Advanced Semiconductor Engineering, Inc., Kaohsiung (TW)

(21) Appl. No.: 18/116,268

(22) Filed: Mar. 1, 2023

(51) Int. Cl. H01L 23/10; H01L 21/50

(52) U.S. Cl. CPC H01L 23/10; H01L 21/50; H01L 24/05; H01L 24/13; H01L 24/16; H01L 24/32; H01L 24/73; H01L 2224/05573; H01L 2224/05611; H01L 2224/05624; H01L 2224/05647; H01L 2224/05655; H01L 2224/0566; H01L 2224/05666; H01L 2224/05671; H01L 2224/13083; H01L 2224/13111; H01L 2224/13124; H01L 2224/13139; H01L 2224/13144; H01L 2224/13147; H01L 2224/13155; H01L 2224/1316; H01L 2224/13164; H01L 2224/13166; H01L 2224/13169; H01L 2224/13171; H01L 2224/16227; H01L 2224/16238; H01L 2224/32225; H01L 2224/73204

(57) ABSTRACT

An interconnection structure and a package structure are provided. The interconnection structure includes a substrate, a conductive layer, a bonding layer, and a moderating layer. The conductive layer is over the substrate and has a top surface. The bonding layer is over the top surface of the conductive layer. The moderating layer is between the conductive layer and the bonding layer and configured to mitigate an increase in a surface roughness of the top surface of the conductive layer during an electroless plating process for forming the bonding layer.

### BACKGROUND

### 1. Technical Field

The present disclosure relates generally to an interconnection structure and a package structure.

### 2. Description of the Related Art

Modern semiconductor packaging has evolved toward increasingly sophisticated integration architecture (e.g., system-in-package (SiP) architecture), which often contains a 2.5D or 3D functional electronic integration with multiple device components integrated in a package structure. For a highly integrated package structure that incorporates multiple device components, the associated fabrication technique is becoming increasingly complicated. For example, one or more reflow operations may be performed for bonding the device components in the manufacturing process. In such a scenario, if the melting point of a solder material in the reflow process is relatively high, the reflow process may likely cause damage to one or more device components.

### SUMMARY

In one or more embodiments, an interconnection structure includes a substrate, a conductive layer, a bonding layer, and a moderating layer. The conductive layer is over the substrate and has a top surface. The bonding layer is over the top surface of the conductive layer. The moderating layer is between the conductive layer and the bonding layer and configured to mitigate an increase in a surface roughness of the top surface of the conductive layer during an electroless plating process for forming the bonding layer.

In one or more embodiments, a package structure includes a first conductive structure, a second conductive structure, and an electroless bonding layer. The second conductive structure faces the first conductive structure. The electroless bonding layer connects the first conductive structure to the second conductive structure, wherein the electroless bonding layer covers a portion of a lateral surface of the first conductive structure.

### BRIEF DESCRIPTION OF THE DRAWINGS

Aspects of the present disclosure are best understood from the following detailed description when read with the accompanying drawings. It is noted that various features may not be drawn to scale, and the dimensions of the various features may be arbitrarily increased or reduced for clarity of discussion.

FIG. 1A is a cross-section of an interconnection structure in accordance with some embodiments of the present disclosure.

FIG. 1B is a top view of an interconnection structure in accordance with some embodiments of the present disclosure.

FIG. 2A is a cross-section of an interconnection structure in accordance with some embodiments of the present disclosure.

FIG. 2B is a cross-section of an interconnection structure in accordance with some embodiments of the present disclosure.

FIG. 2C is a cross-section of an interconnection structure in accordance with some embodiments of the present disclosure.

FIG. 2D is a cross-section of an interconnection structure in accordance with some embodiments of the present disclosure.

FIG. 2E is a cross-section of an interconnection structure in accordance with some embodiments of the present disclosure.

FIG. 2F is a cross-section of an interconnection structure in accordance with some embodiments of the present disclosure.

FIG. 3A is a cross-section of a package structure in accordance with some embodiments of the present disclosure.

FIG. 3B is a cross-section of a package structure in accordance with some embodiments of the present disclosure.

FIG. 3C is a cross-section of a package structure in accordance with some embodiments of the present disclosure.

FIG. 3D is a cross-section of a package structure in accordance with some embodiments of the present disclosure.

FIG. 3E is a cross-section of a package structure in accordance with some embodiments of the present disclosure.

FIG. 3F is a cross-section of a package structure in accordance with some embodiments of the present disclosure.

FIG. 4 s a cross-section of a package structure in accordance with some embodiments of the present disclosure.

FIG. 5A, FIG. 5B, FIG. 5C, and FIG. 5D illustrate various operations in a method of manufacturing an interconnection structure in accordance with some embodiments of the present disclosure.

FIG. 6A and FIG. 6B illustrate various operations in a method of manufacturing a package structure in accordance with some embodiments of the present disclosure.

FIG. 7A, FIG. 7B, and FIG. 7C illustrate various operations in a method of manufacturing a package structure in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

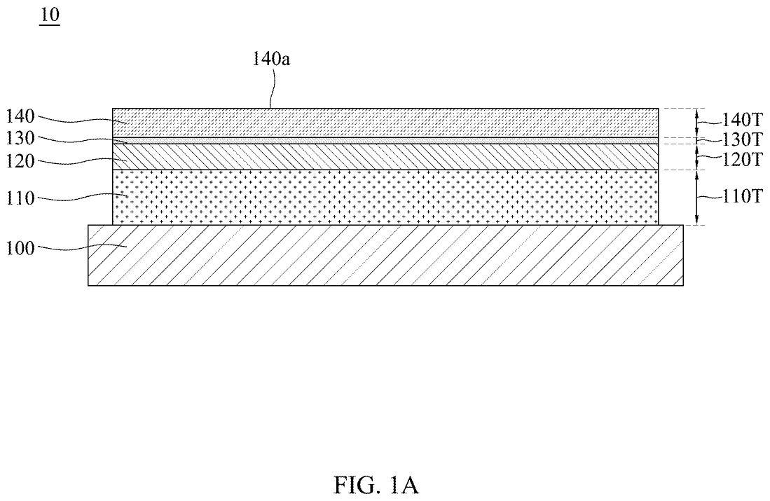

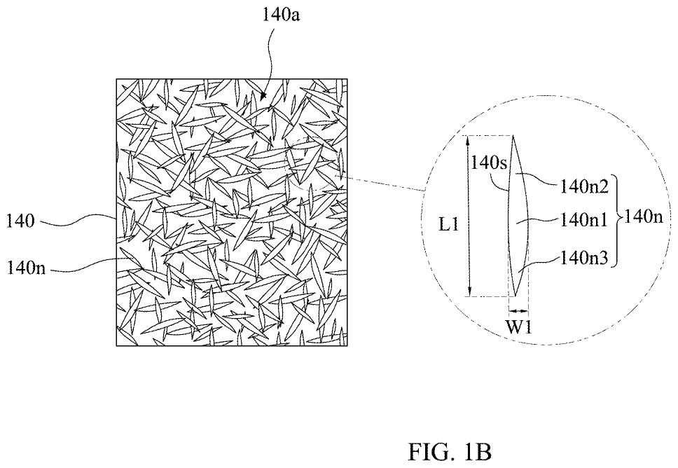

FIG. 1A is a cross-section of an interconnection structure 10 in accordance with some embodiments of the present disclosure. The interconnection structure 10 includes a conductive layer 110, a barrier 120, a moderating layer 130, and a bonding layer 140.

The substrate 100 may include, for example, a printed circuit board (PCB), such as a paper-based copper foil laminate, a composite copper foil laminate, or a polymer-impregnated glass-fiber-based copper foil laminate. The substrate 100 may include a redistribution layer (RDL) including one or more conductive traces and/or one or more conductive through vias. In some embodiments, the substrate 100 includes a ceramic material or a metal plate. In some embodiments, the substrate 100 may include an organic substrate or a leadframe. In some embodiments, the substrate 100 may include a two-layer substrate which includes a core layer and a conductive material and/or structure disposed on an upper surface and a bottom surface of the substrate 100. The conductive material and/or structure may include a plurality of traces. The substrate 100 may include a device component, such as an electronic component. The substrate 100 may include a package including one or more components. The substrate 100 may be or include a carrier.

The conductive layer 110 may be disposed over the substrate 100. In some embodiments, the conductive layer 110 may be or include a metal layer. In some embodiments, the conductive layer 110 may be or include a pad, e.g., a conductive pad. The conductive layer 110 may be referred to as a pad (or “a first pad”) of the substrate 100. The conductive layer 110 may be formed of or include a conductive material such as a metal or metal alloy. Examples include aluminum (Al), copper (Cu), titanium (Ti), nickel (Ni), chromium (Cr), tin (Sn), iron (Fe), or an alloy thereof. In some embodiments, the conductive layer 110 is or includes a Cu layer or a Cu pad.

The barrier 120 may be disposed over the conductive layer 110. In some embodiments, the barrier 120 is between the conductive layer 110 and the moderating layer 130. In some embodiments, a thickness 120T of the barrier 120 is less than a thickness 110T of the conductive layer 110. In some embodiments, the barrier 120 may be or include a metal layer. In some embodiments, the barrier 120 may be or include a pad, e.g., a conductive pad. The barrier 120 may be formed of or include a conductive material such as a metal or metal alloy. Examples include Al, Cu, Ti, Ni, Cr, Sn, Fe, or an alloy thereof. In some embodiments, the barrier 120 is or includes a Ni layer or a Ni pad.

In some embodiments, a metal reactivity of the barrier 120 may be greater than a metal reactivity of the conductive layer 110. The term “metal reactivity” used hereinafter may refer to a flexibility of a metal being replaced. The term “metal reactivity” used hereinafter may refer to a reactivity of a metal with a hydrogen ion-source (e.g., water and/or acids) in a replacement reaction. The term “metal reactivity” used hereinafter may refer to a reducing ability or a reducing power of a metal.

The moderating layer 130 may be disposed over the conductive layer 110. In some embodiments, the moderating layer 130 is disposed over the barrier 120. In some embodiments, the moderating layer 130 is disposed between the barrier 120 and the bonding layer 140. In some embodiments, the moderating layer 130 is between the conductive layer 110 and the bonding layer 140 and configured to mitigate an increase in a surface roughness of a top surface 110a of the conductive layer 110 during an electroless plating process for forming the bonding layer 140. The moderating layer 130 may be referred to as an intermediate metal layer. In some embodiments, a thickness 130T of the moderating layer 130 is less than the thickness 120T of the barrier 120. In some embodiments, the moderating layer 130 may be or include a metal layer. In some embodiments, the moderating layer 130 may be or include a pad, e.g., a conductive pad. The moderating layer 130 may be formed of or include a conductive material such as a metal or metal alloy. Examples include Au, Pt, Pd, or an alloy thereof. In some embodiments, the moderating layer 130 is or includes an Au layer, an Au pad, a Pt layer, or a Pt pad. In some embodiments, the metal reactivity of the conductive layer 110 is greater than a metal reactivity of the moderating layer 130. In some embodiments, the metal reactivity of the barrier 120 is greater than a metal reactivity of the moderating layer 130.

The bonding layer 140 (also referred to as “the electroless bonding layer”) may be disposed over the moderating layer 130. In some embodiments, a thickness 140T of the bonding layer 140 is greater than the thickness 130T of the moderating layer 130. In some embodiments, the thickness 140T of the bonding layer 140 is less than the thickness 110T of the conductive layer 110. In some embodiments, the thickness 140T of the bonding layer 140 is equal to or greater than about 1 μm, about 5 μm, or about 8 μm. In some embodiments, the thickness 140T of the bonding layer 140 is from about 1 μm to about 10 μm or from about 1.5 μm to about 9 μm. In some embodiments, the bonding layer 140 may be or include a metal layer. In some embodiments, the bonding layer 140 may be or include a pad, e.g., a conductive pad. The bonding layer 140 may be formed of or include a conductive material such as a metal or metal alloy. Examples include Ag or an alloy thereof. In some embodiments, the bonding layer 140 is or includes an Ag layer or an Ag pad.

In some embodiments, a metal reactivity of the bonding layer 140 is greater than the metal reactivity of the moderating layer 130. In some embodiments, the metal reactivity of the bonding layer 140 is less than the metal reactivity of the conductive layer 110. In some embodiments, the metal reactivity of the bonding layer 140 is less than the metal reactivity of the barrier 120. In some embodiments, the bonding layer 140 has a surface 140a (also referred to as “a top surface”) configured to bond to another layer or pad that is external to the interconnection structure 10.

FIG. 1B is a top view of an interconnection structure 10 in accordance with some embodiments of the present disclosure. In some embodiments, FIG. 1B shows a top view of the surface 140a (or the top surface) of the bonding layer 140.

In some embodiments, the bonding layer 140 includes a plurality of nano-particles 140n. The nano-particles 140n may be stacked over one another to form the layer of the bonding layer 140. In some embodiments, the bonding layer 140 is free of a dendrite structure. In some embodiments, a sintering temperature of the nano-particles 140n is lower than a melting temperature of the nano-particles 140n.

In some embodiments, the nano-particles 140n are or include whisker-like nano-particles. In some embodiments, the nano-particles 140n are or include needle-like nano-particles. In some embodiments, a length L1 of the nano-particle 140n may range from about 1 μm to about 4 μm, from about 1.5 μm to about 3.5 μm, or from about 2 μm to about 3 μm. In some embodiments, the nano-particle 140n includes a center portion 140n1 and end portions 140n2 and 140n3 extending from the center portion 140n1. In some embodiments, a width W1 of the nano-particle 140n tapers from the center portion 140n1 to the end portion 140n2. In some embodiments, the width W1 of the nano-particle 140n tapers from the center portion 140n1 to the end portion 140n3. In some embodiments, the end portions 140n2 and 140n3 of the nano-particle 140n are or include tips. In some embodiments, the nano-particle 140n has a curved surface 140s (also referred to as “a curved lateral surface”) converged at two end portions 140n2 and 140n3 to form the two tips. In some embodiments, the two curved surface 140s of a single nano-particle 140n from a top view perspective may have different radius of curvatures.

In some embodiments, at least two or more of the nano-particles 140n extend in different directions from a top view perspective. The orientation which the length L1 extends in each of the nano-particles 140n can be arbitrary. In some embodiments, at least two or more of the nano-particles 140n have different lengths L1. In some embodiments, at least two or more of the nano-particles 140n have different width W1. In some embodiments, at least two or more of the curved surfaces 140s of the nano-particles 140n have different curvatures. In some embodiments, at least two or more of the nano-particles 140n have different aspect ratios (e.g., the ratio of the length L1 to the width W1).

Table 1 shows experimental results of oxygen contents in an upmost layer of interconnection structures of an embodiment E1 and a comparative embodiment C1 after an annealing operation being performed or not. The interconnection structure of embodiment E1 has a structure illustrated in FIG. 1A with the bonding layer 140 including whisker-like metal nano-particles (e.g., the whisker-like metal nano-particles 140n illustrated in FIG. 1B) and free of a dendrite structure. The bonding layer 140 includes Ag, the moderating layer 130 includes Au, the barrier 120 includes Ni, the conductive layer 110 includes Cu, and the bonding layer 140 is the upmost layer of the interconnection structure. The interconnection structure of comparative embodiment C1 has a structure including a conductive layer 110 formed on a substrate 100, and the conductive layer 110 being a Cu layer is the upmost layer of the interconnection structure.

TABLE 1

| Annealing under | C1 | | E1 | |
|---|---|---|---|---|
| 200° C. for 2.5 | With | Without | With | Without |
| hours | annealing | annealing | annealing | annealing |
| Copper (wt %) | 100 | 97.9 | 1.20 | 5.28 |
| Silver (wt %) | NA | NA | 98.80 | 94.72 |
| Oxygen (wt %) | 0 | 2.10 | 0 | 0 |

According to the results shown in table 1, the Cu layer of the interconnection structure of comparative embodiment C1 is oxidized after annealing. In contrast, it is apparent that the bonding layer 140 of the interconnection structure of embodiment E1 is free from being oxidized after annealing.

According to some embodiments of the present disclosure, with the design of the bonding layer 140 including nano-particles 140n (e.g., whisker-like nano-particles), a sintering temperature of the bonding layer 140 may be reduced to be lower than a melting temperature of the bonding layer 140. Therefore, the bonding layer 140 may be bonded to an external layer, pad, or structure (e.g., the conductive layer 210 or the bonding layer 150, which will be discussed in details hereinafter) under the relatively low sintering temperature rather than the relatively high melting temperature. Thus, damage to structures or components by a relatively high sintering temperature during the bonding operation can be prevented, and the energy for the bonding operation can be reduced, thereby reducing the cost.

In addition, while a metal layer having a relatively high metal reactivity (e.g., the conductive layer 110 and the barrier 120) may be easily oxidized, which may adversely affect the bonding strength. In contrast, according to some embodiments of the present disclosure, the bonding layer 140 formed on the conductive layer 110 and the barrier 120 and having a relatively low metal reactivity can protect the conductive layer 110 and the barrier 120 from being oxidized. Moreover, the bonding layer 140 having a relatively low metal reactivity may be free from being oxidized. Therefore, the interconnection structure 10 can be relatively stable without being oxidized from a relatively long time prior to proceeding following bonding operations. Thus, the Q-time for the interconnection structure 10 can be increased, and the yield of the bonding operation using the interconnection structure 10 can be increased as well.

Moreover, when the bonding layer 140 is directly formed on a metal layer (e.g., the conductive layer 110) having a metal reactivity greater than that of the bonding layer 140, the bonding layer 140 including dendrite structures may be formed. The dendrite structures may be formed by a replacement reaction where metal atoms of the conductive layer 110 are oxidized and replaced to generate electrons and metal ions, and the electrons then react with metal ions in the precursor solution to form the dendrite structures of the bonding layer 140 directly on the conductive layer 110. Defects or voids may be generated at the interface between the conductive layer 110 and the bonding layer 140 since portions of the structure are consumed during the replacement reaction (e.g., the top surface of the conductive layer 110 may be non-uniform), and thus dendrite structures may be formed directly on the conductive layer 110. The dendrite structures may grow upwards from the top surface of the conductive layer 110, and thus voids between and within the dendrite structures may adversely affect the formation of the layer of the bonding layer 140. Therefore, the uniformity of the as-formed bonding layer 140 may be poor, and the thickness of the as-formed bonding layer 140 may be relatively thin. In contrast, according to some embodiments of the present disclosure, with the design of the moderating layer 130 formed between the bonding layer 140 and the conductive layer 110 and having a metal reactivity less than that of the bonding layer 140, the moderating layer 130 can provide a relatively uniform surface (or uniform top surface) for the bonding layer 140 to be formed thereon, thus the as-formed bonding layer 140 can be free of a dendrite structure and have a relatively large thickness 140T. Therefore, formation of voids or air gaps between the bonding layer 140 and the external layer, pad, or structure (e.g., the conductive layer 210 or the bonding layer 150, which will be discussed in details hereinafter) that bonds to the bonding layer 140 can be prevented, and the bonding strength as well as the yield of the bonding operation can be improved.

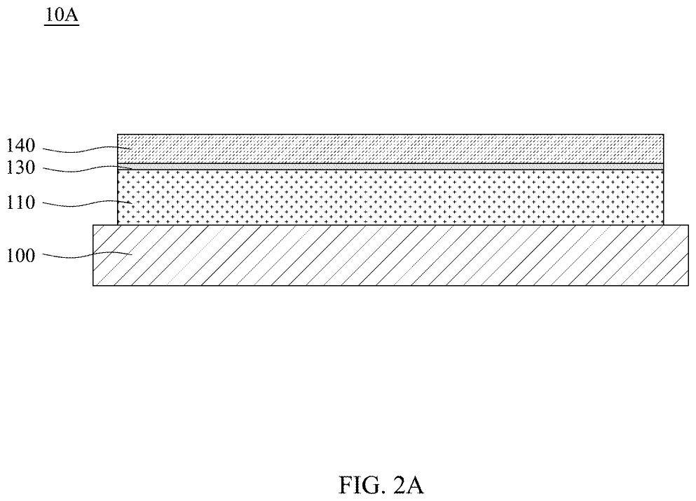

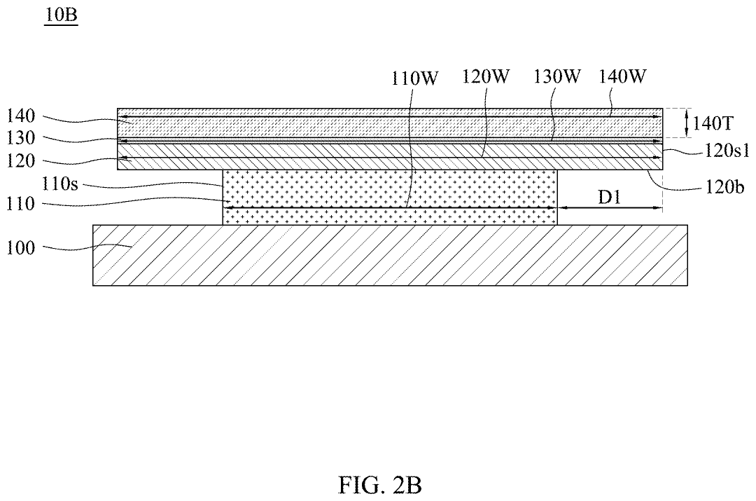

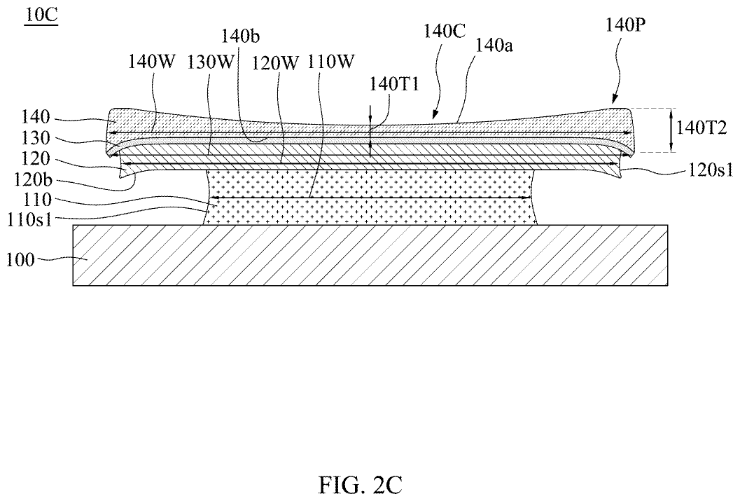

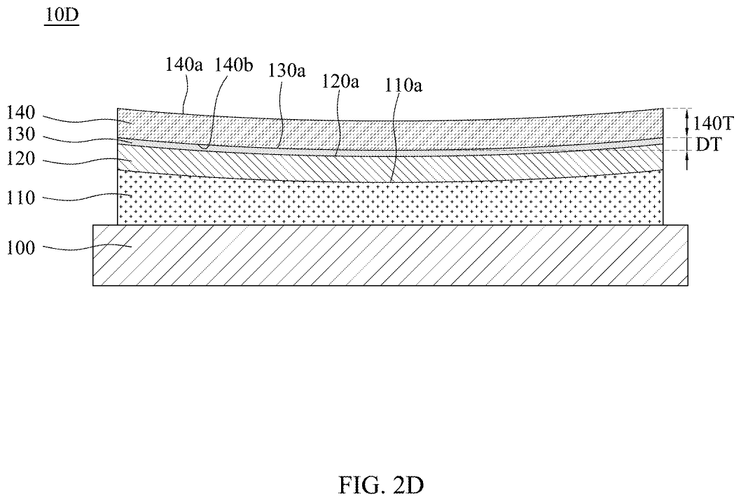

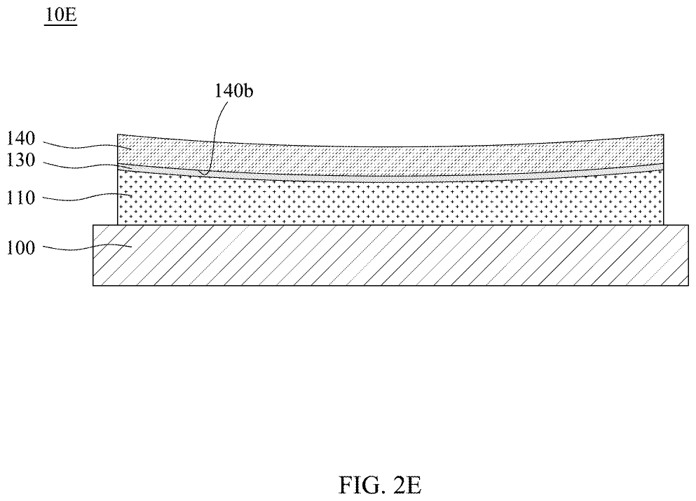

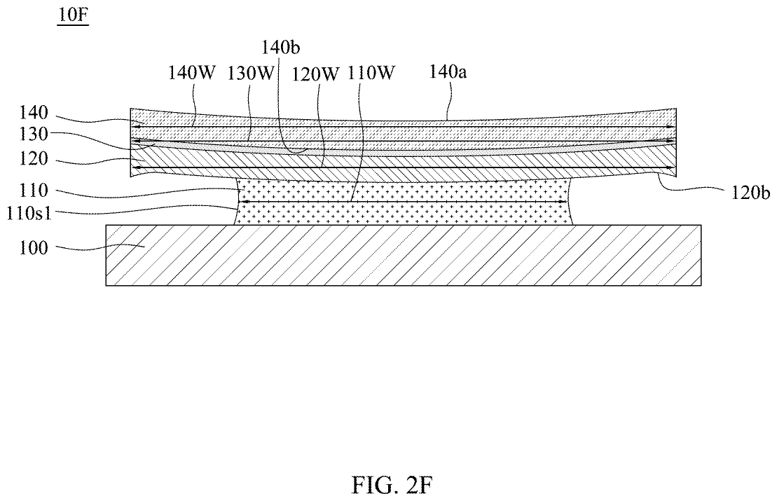

FIG. 2A is a cross-section of an interconnection structure 10A in accordance with some embodiments of the present disclosure. The interconnection structure 10A is similar to the interconnection structure 10 in FIG. 1A, with differences therebetween as follows.

In some embodiments, the interconnection structure 10A is free of the barrier 120. In some embodiments, the conductive layer 110 includes a Cu layer, the moderating layer 130 includes an Au layer over the Cu layer, and the bonding layer 140 includes an Ag layer contacting the Au layer.

FIG. 2B is a cross-section of an interconnection structure 10B in accordance with some embodiments of the present disclosure. The interconnection structure 10B is similar to the interconnection structure 10 in FIG. 1A, with differences therebetween as follows.

In some embodiments, a width 110W of the conductive layer 110 is less than a width 120W of the barrier 120. In some embodiments, a portion of a bottom surface 120b of the barrier 120 is exposed from the conductive layer 110. In some embodiments, at least a sidewall 110s1 of the conductive layer 110 is recessed with respect to at least a sidewall 120s1 of the barrier 120. In some embodiments, the sidewall 110s2 is recessed with respect to the sidewall 120s1 by a distance D1 of about 2.5 μm or above. In some embodiments, the distance D1 is from about 2.5 μm to about 220 μm. In some embodiments, a surface roughness of the sidewall 110s1 of the conductive layer 110 is greater than a surface roughness of the surface 140a (or the top surface) of the bonding layer 140. In some embodiments, the thickness 140T of the bonding layer 140 is from about 0.1 μm to about 9 μm.

In some embodiments, the width 110W of the conductive layer 110 is less than a width 130W of the moderating layer 130. In some embodiments, the width 110W of the conductive layer 110 is less than a width 140W of the bonding layer 140.

FIG. 2C is a cross-section of an interconnection structure 10C in accordance with some embodiments of the present disclosure. The interconnection structure 10C is similar to the interconnection structure 10B in FIG. 2B, with differences therebetween as follows.

In some embodiments, the sidewall 110s1 of the conductive layer 110 includes a curved surface concave toward a center of the conductive layer 110.

In some embodiments, the width 120W of the barrier 120 is greater than the width 110W of the conductive layer 110. In some embodiments, the width 120W of the barrier 120 is less than the width 130W of the moderating layer 130 and the width 140W of the bonding layer 140. In some embodiments, a portion of the bottom surface 120b of the barrier 120 is exposed from the conductive layer 110 and concave toward a center of the barrier 120. In some embodiments, the sidewall 120s1 of the barrier 120 includes a curve surface concave toward a center of the barrier 120.

In some embodiments, the bonding layer 140 includes a central portion 140C and a peripheral portion 140P adjacent to the central portion 140C, and a thickness 140T1 of the central portion 140C is less than a thickness 140T2 of the peripheral portion 140P. In some embodiments, the bonding layer 140 has a curved top surface (e.g., the surface 140a) concave toward a center of the bonding layer 140. In some embodiments, the bonding layer 140 has a curved bottom surface (e.g., a surface 140b opposite to the surface 140a) concave toward the center of the bonding layer 140.

FIG. 2D is a cross-section of an interconnection structure 10D in accordance with some embodiments of the present disclosure. The interconnection structure 10D is similar to the interconnection structure 10 in FIG. 1A, with differences therebetween as follows.

In some embodiment, the conductive layer 110 has a curved top surface 110a concave toward a center of the conductive layer 110. In some embodiment, the barrier 120 has a curved top surface 120a concave toward a center of the barrier 120. In some embodiment, the moderating layer 130 has a curved top surface 130a concave toward a center of the moderating layer 130. In some embodiments, the bonding layer 140 has a curved bottom surface (e.g., the surface 140b) convex towards the moderating layer 130. In some embodiments, the curved top surface 110a of the conductive layer 110 may be formed by a polishing operation, e.g., a chemical mechanical polishing (CMP) operation. The curved top surface 110a may be formed due to a dishing effect resulted from the polishing operation. The curved surfaces of the barrier 120 and the moderating layer 130 and the bonding layer 140 may be formed by conformally depositing the metal barrier 120 and the moderating layer 130 and the bonding layer 140 on the curved top surface 110a of the conductive layer 110.

In some embodiments, the thickness 140T of the bonding layer 140 is equal to or greater than about 0.8 μm, about 1 μm, about 5 μm, or about 8 μm. In some embodiments, the thickness 140T of the bonding layer 140 is from about 1 μm to about 10 μm or from about 1.5 μm to about 9 μm. In some embodiments, the thickness 140T of the bonding layer 140 is greater than a recessed depth DT (also referred to as “a dishing depth”) of the top surface 130a of the moderating layer 130.

FIG. 2E is a cross-section of an interconnection structure 10E in accordance with some embodiments of the present disclosure. The interconnection structure 10E is similar to the interconnection structure 10D in FIG. 2D, with differences therebetween as follows.

In some embodiments, the interconnection structure 10E is free of the barrier 120. In some embodiments, the conductive layer 110 includes a Cu layer, the moderating layer 130 includes an Au layer over the Cu layer, and the bonding layer 140 includes an Ag layer contacting the Au layer.

FIG. 2F is a cross-section of an interconnection structure 2F in accordance with some embodiments of the present disclosure. The interconnection structure 10F is similar to the interconnection structure 10D in FIG. 2D, with differences therebetween as follows.

In some embodiments, the width 120W of the barrier 120 is greater than the width 110W of the conductive layer 110. In some embodiments, the width 130W of the moderating layer 130 is greater than the width 110W of the conductive layer 110. In some embodiments, the width 140W of the bonding layer 140 is greater than the width 110W of the conductive layer 110. In some embodiments, a portion of the bottom surface 120b of the barrier 120 is exposed from the conductive layer 110 and concave toward a center of the barrier 120. In some embodiments, at least a sidewall 110s1 of the conductive layer 110 is recessed with respect to at least a sidewall 120s1 of the barrier 120. In some embodiments, a surface roughness of the sidewall 110s1 of the conductive layer 110 is greater than a surface roughness of the surface 140a (or the top surface) of the bonding layer 140. In some embodiments, the sidewall 110s1 of the conductive layer 110 includes a curve surface concave toward a center of the conductive layer 110.

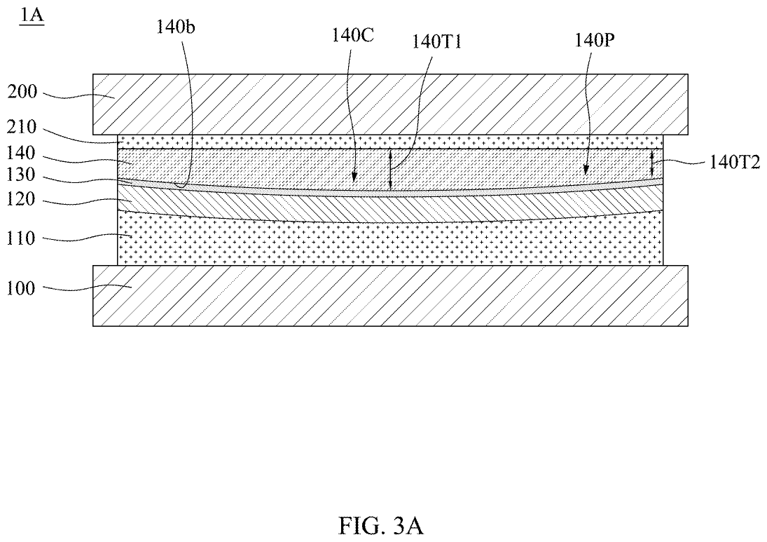

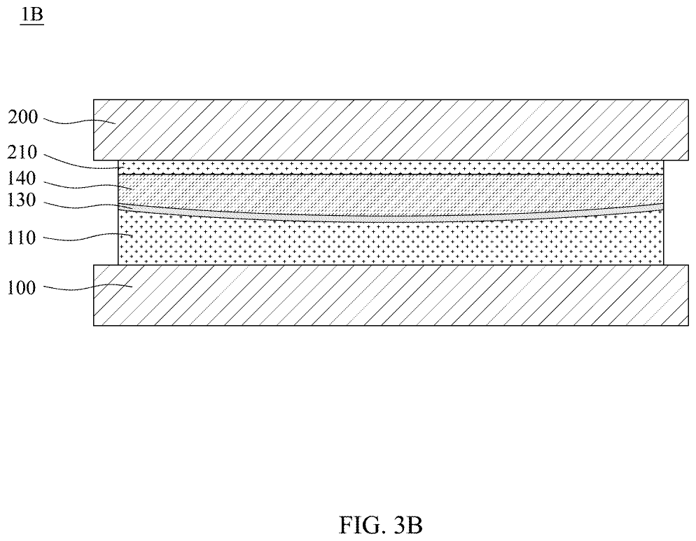

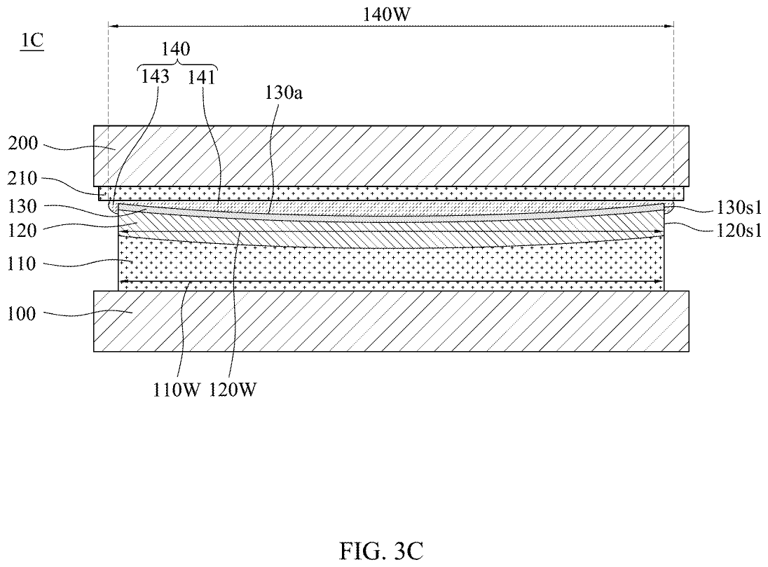

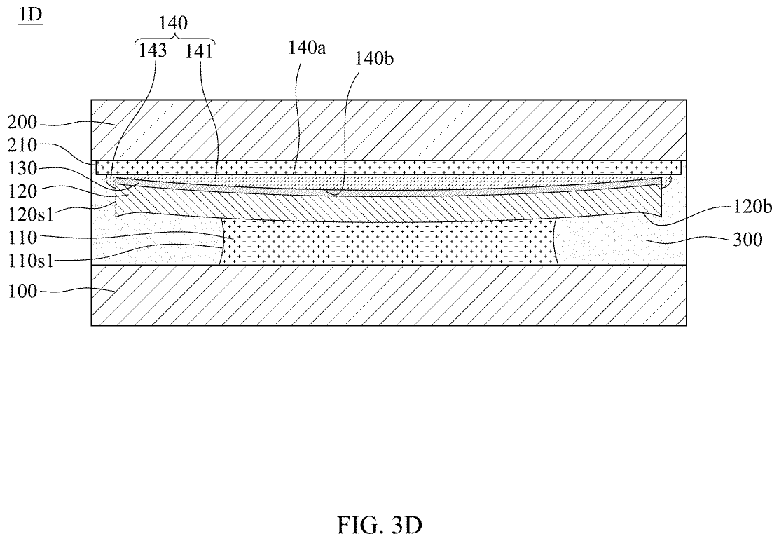

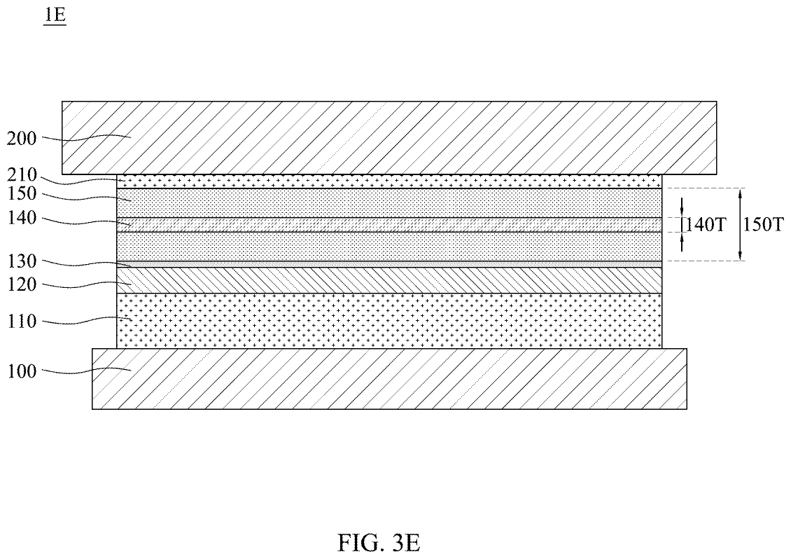

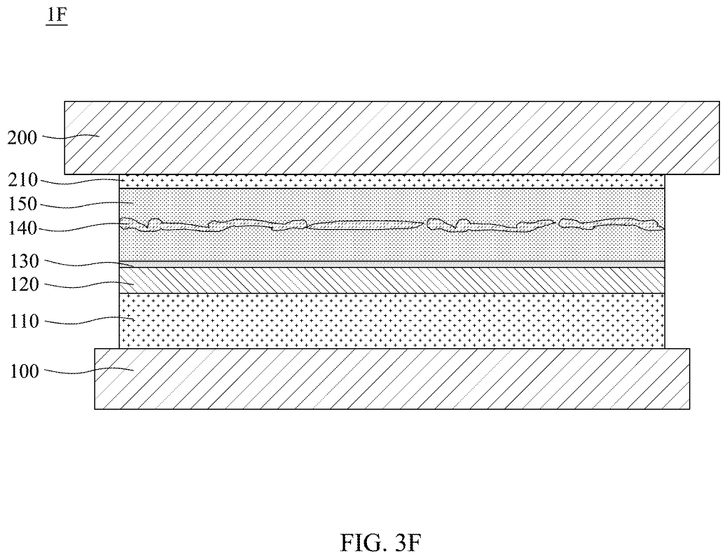

FIG. 3A is a cross-section of a package structure 1A in accordance with some embodiments of the present disclosure. In some embodiments, the package structure 1A includes substrates 100 and 200, conductive layers 110 and 210, a barrier 120, a moderating layer 130, and a bonding layer 140. The materials of the substrates 100 and 200, the conductive layers 110 and 210, the barrier 120, the moderating layer 130, and the bonding layer 140 are described above and omitted hereinafter. In some embodiments, the conductive layer 110, the barrier 120, and the moderating layer 130 may collectively form a conductive structure (also referred to as “a first conductive structure”).

The substrate 200 may be disposed over the substrate 100. The carrier 200 may include, for example, a printed circuit board, such as a paper-based copper foil laminate, a composite copper foil laminate, or a polymer-impregnated glass-fiber-based copper foil laminate. The substrate 200 may include a redistribution layer (RDL) including one or more conductive traces and/or one or more conductive through vias. In some embodiments, the substrate 200 includes a ceramic material or a metal plate. In some embodiments, the substrate 200 may include an organic substrate or a leadframe. In some embodiments, the substrate 200 may include a two-layer substrate which includes a core layer and a conductive material and/or structure disposed on an upper surface and a bottom surface of the substrate 200. The conductive material and/or structure may include a plurality of traces. The substrate 200 may include a device component, such as an electronic component. The substrate 200 may include a package including one or more components. The substrate 200 may be or include a carrier.

The conductive layer 210 may be disposed over the substrate 200. In some embodiments, the conductive layer 210 may be or include a metal layer. In some embodiments, the conductive layer 210 may be or include a pad, e.g., a conductive pad. The conductive layer 210 may be referred to as a pad (or “a second pad”) of the substrate 200. The conductive layer 210 may be formed of or include a conductive material such as a metal or metal alloy. Examples include Al, Cu, Ti, Ni, Cr, Sn, Fe, or an alloy thereof. In some embodiments, the conductive layer 210 is or includes a Cu layer or a Cu pad.

In some embodiments, the bonding layer 140 (or the electroless bonding layer) connects the substrate 100 to the substrate 200. In some embodiments, the electroless bonding layer 140 connects the first conductive structure (e.g., the conductive layer 110, the barrier 120, and the moderating layer 130) to the second conductive structure (e.g., the conductive layer 210). In some embodiments, the electroless bonding layer 140 covers a portion of a lateral surface of the first conductive structure. In some embodiments, the bonding layer 140 connects the first pad of the substrate 100 (e.g., the conductive layer 110) to the second pad of the substrate 200 (e.g., the conductive layer 210). In some embodiments, the bonding layer 140 has a curved bottom surface (e.g., the surface 140b) concave toward the moderating layer 130. In some embodiments, the bonding layer 140 has a substantially flat top surface (e.g., the surface 140a) opposite to the curved bottom surface (e.g., the surface 140b). In some embodiments, the bonding layer 140 includes a central portion 140C and a peripheral portion 140P adjacent to the central portion 140C, and the thickness 140T1 of the central portion 140C is greater than the thickness 140T2 of the peripheral portion 140P. In some embodiments, the bonding layer 140 is configured to bond the first pad of the substrate 100 (e.g., the conductive layer 110) with the second pad of the substrate 200 (e.g., the conductive layer 210) at a temperature lower than a melting temperature of the bonding layer 140.

In some embodiments, the moderating layer 130 (or the intermediate metal layer) is between the first pad of the substrate 100 (e.g., the conductive layer 110) and the bonding layer 140. In some embodiments, a metal reactivity of the bonding layer 140 is greater than a metal reactivity of the moderating layer 130.

In some embodiments, the first pad (e.g., the conductive layer 110) connects the substrate 100 to the moderating layer 130, and a metal reactivity of the first pad is greater than the metal reactivity of the moderating layer 130.

In some embodiments, the second pad (e.g., the conductive layer 210) is facing the first pad (e.g., the conductive layer 110). In some embodiments, the second pad (e.g., the conductive layer 210) connects the substrate 200 to the bonding layer 140, and a metal reactivity of the second pad is greater than the metal reactivity of the bonding layer 140.

FIG. 3B is a cross-section of a package structure 1B in accordance with some embodiments of the present disclosure. The package structure 1B is similar to the package structure 1A in FIG. 3A, with differences therebetween as follows. In some embodiments, the package structure 1B is free of the barrier 120.

FIG. 3C is a cross-section of a package structure 1C in accordance with some embodiments of the present disclosure. The package structure 1C is similar to the package structure 1A in FIG. 3A, with differences therebetween as follows.

In some embodiments, the bonding layer 140 contacts a top surface 130a and a lateral surface 130s1 (or a sidewall) of the moderating layer 130. In some embodiments, the bonding layer 140 includes portions 141 and 143. In some embodiments, the portion 141 is between the carrier 200 and the top surface 130a of the moderating layer 130, and the portion 143 is protruded from the lateral surface 130s1 of the moderating layer 130. The portion 143 may be formed by pressing the conductive layer 210 against the bonding layer 140 in a thermal bonding process, so that a portion of the softened bonding layer 140 is squeezed out of the space between the conductive layers 110 and 210.

In some embodiments, the barrier 120 is disposed between the first pad (e.g., the conductive layer 110) and the moderating layer 130. In some embodiments, the portion 143 of the bonding layer 140 further contacts the barrier 120. In some embodiments, the bonding layer 140 further contacts a lateral surface (e.g., the sidewall 120s1) of the barrier 120. In some embodiments, the width 140W of the bonding layer 140 is greater than the width 120W of the barrier 120. In some embodiments, the width 140W of the bonding layer 140 is greater than the width 110W of the conductive layer 110.

FIG. 3D is a cross-section of a package structure 1D in accordance with some embodiments of the present disclosure. The package structure 1D is similar to the package structure 1C in FIG. 3C, with differences therebetween as follows.

In some embodiments, the package structure 1D further includes a dielectric structure 300 between the substrate 100 and the substrate 200. In some embodiments, the dielectric structure 300 encapsulates the conductive layers 110 and 210, the barrier 120, the moderating layer 130, and the bonding layer 140. The dielectric structure 300 may include an encapsulant, an underfill, one or more dielectric layers, or a combination thereof.

In some embodiments, a portion of the bottom surface 120b of the barrier 120 is exposed from the conductive layer 110 and concave toward a center of the barrier 120. In some embodiments, at least a sidewall 110s1 of the conductive layer 110 is recessed with respect to at least a sidewall 120s1 of the barrier 120. In some embodiments, a surface roughness of the sidewall 110s1 of the conductive layer 110 is greater than a surface roughness of the surface 140a (or the top surface) of the bonding layer 140. In some embodiments, the sidewall 110s1 of the conductive layer 110 includes a curve surface concave toward a center of the conductive layer 110.

FIG. 3E is a cross-section of a package structure 1E in accordance with some embodiments of the present disclosure. In some embodiments, the package structure 1E includes substrates 100 and 200, conductive layers 110 and 210, a barrier 120, a moderating layer 130, a bonding layer 140, and a bonding layer 150. The materials of the substrates 100 and 200, the conductive layers 110 and 210, the barrier 120, the moderating layer 130, and the bonding layer 140 are described above and omitted hereinafter.

In some embodiments, the substrate 100 includes a first pad (e.g., the conductive layer 110), the substrate 200 includes a second pad (e.g., the conductive layer 210), and the bonding layer 150 is between the first pad and the second pad.

In some embodiments, the bonding layer 140 is within the bonding layer 150. In some embodiments, the bonding layer 140 is spaced apart from the first pad (e.g., the conductive layer 110) and the second pad (e.g., the conductive layer 210). In some embodiments, the bonding layer 140 includes whisker-like metal nano-particles (e.g., the whisker-like metal nano-particles 140n illustrated in FIG. 1C). In some embodiments, a thickness 140T of the bonding layer 140 is less than a thickness 150T of the bonding layer 150.

In some embodiments, the bonding layer 150 includes a soldering material. For example, the bonding layer 150 may include Sn. In some embodiments, the bonding layer 150 is free of an intermetallic compound (IMC). In some embodiments, one or more interfaces between the bonding layer 150 and the bonding layer 140 may be free of an IMC. In some embodiments, the bonding layer 150 is free of an IMC of the bonding layer 150 and one or more metals from one or more of the layers 110, 120, and 130. In some embodiments, the bonding layer 150 is free of AuSn₄ and NiSn₄, and thus the bonding strength of the bonding layer 150 is relatively satisfactory. In some embodiments, a melting temperature of the bonding layer 140 is greater than a melting temperature of the bonding layer 150. In some embodiments, a sintering temperature of the bonding layer 140 is lower than the melting temperature of the bonding layer 150. In some embodiments, the bonding layer 150 contacts the moderating layer 130 having a metal reactivity less than that of the bonding layer 140.

FIG. 3F is a cross-section of a package structure 1F in accordance with some embodiments of the present disclosure. The package structure 1F is similar to the package structure 1E in FIG. 3E, with differences therebetween as follows.

In some embodiments, the bonding layer 140 has a non-uniform thickness. In some embodiments, the bonding layer 140 includes a plurality of portions or segments dispersed within the bonding layer 150. There portions or segments of the bonding layer 140 are at substantially the same elevation. In some embodiments, two or more of the portions or segments of the bonding layer 140 are spaced apart from each other by the bonding layer 150.

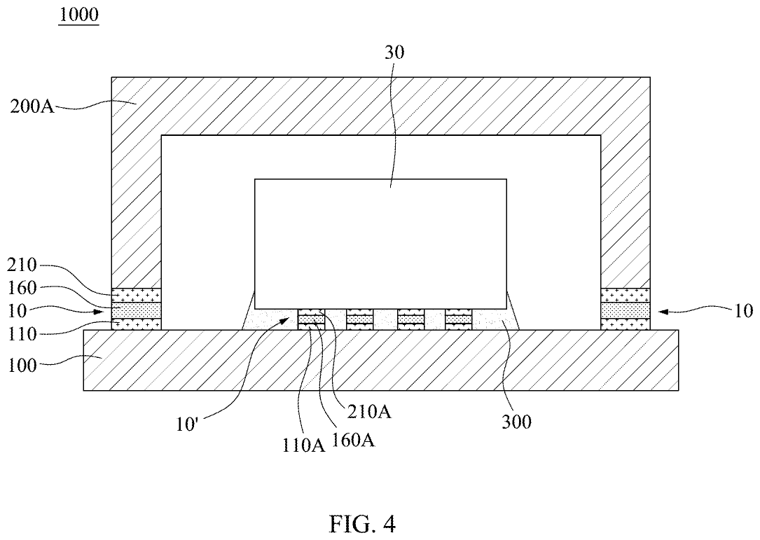

FIG. 4 is a cross-section of a package structure 1000 in accordance with some embodiments of the present disclosure. In some embodiments, the package structure 1000 includes a substrate 100, a cover 200A, interconnection structures 10 and 10′, a dielectric structure 300, and an electronic component 30. The materials of the carrier 10 and the dielectric structure 300 are described above and omitted hereinafter.

The interconnection structures 10 and 10′ may each include a structure illustrated in FIGS. 1A to 2F. The structures (or the bonding structures or the interconnection structures) between the conductive layer 110 and the conductive layer 210 may each include a structure illustrated in FIGS. 3A to 3F. In some embodiments, the interconnection structure 10 includes conductive layers 110 and 210 and a bonding structure 160, and the interconnection structure 10′ includes conductive layers 110A and 210A and a bonding structure 160A. The material of the conductive layer 110A may be the same as or similar to that of the conductive layer 110, and the material of the conductive layer 210A may be the same as or similar to that of the conductive layer 210. In some embodiments, each of the bonding structures 160 and 160A may include the barrier 120, the moderating layer 130, and the bonding layer 140 described above. In some embodiments, each of the bonding structures 160 and 160A may include the moderating layer 130 and the bonding layer 140 described above. In some embodiments, each of the bonding structures 160 and 160A may include the barrier 120, the moderating layer 130, the bonding layer 140, and the bonding layer 150 described above.

In some embodiments, the electronic component 30 may electrically connected to the substrate 100 through the interconnection structure 10′. The dielectric structure 300 may cover or encapsulate the interconnection structures 10′. The electronic component 30 may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof.

In some embodiments, the cover 200A is connected to the substrate 100 through one or more of the interconnection structures 10. The cover 200A and the substrate 100 may define a space for accommodating the electronic component 30.

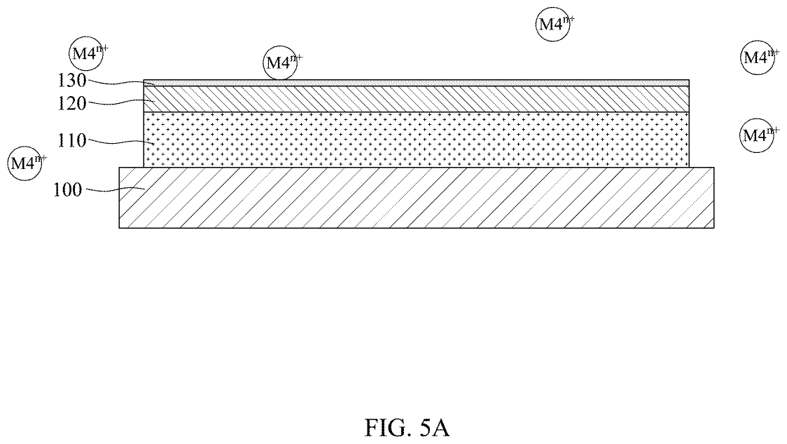

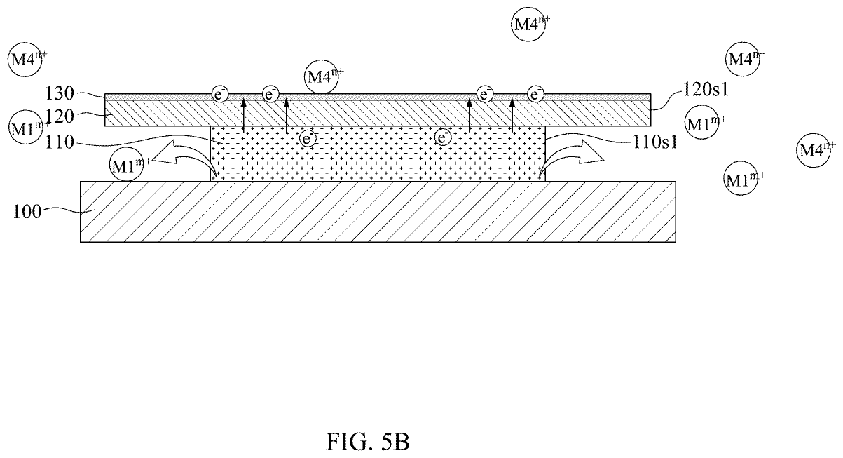

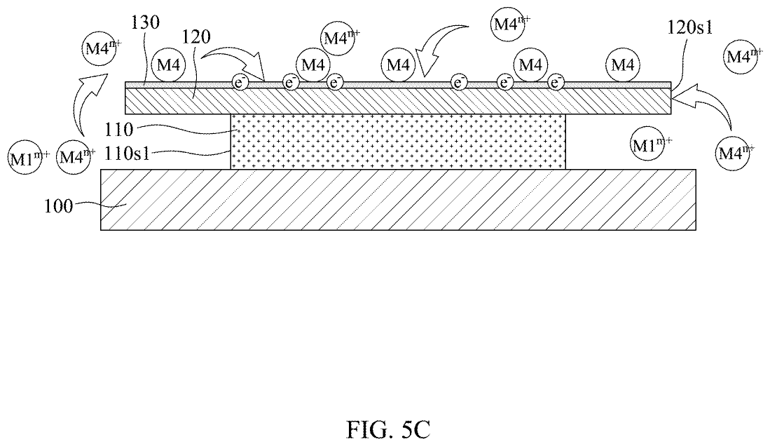

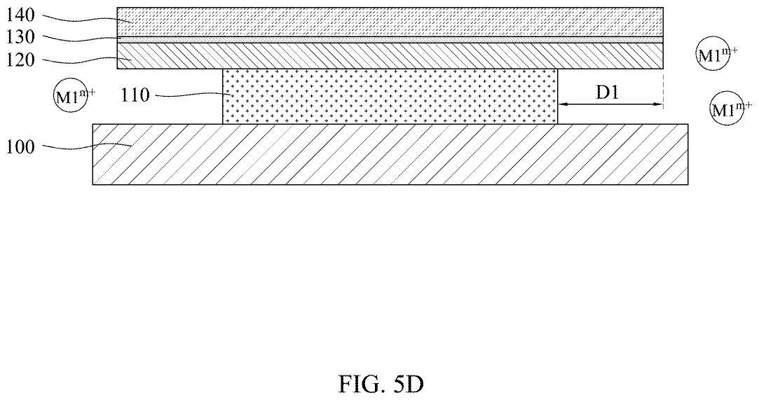

FIG. 5A, FIG. 5B, FIG. 5C, and FIG. 5D illustrate various operations in a method of manufacturing an interconnection structure 10B in accordance with some embodiments of the present disclosure.

Referring to FIG. 5A, a conductive layer 110 may be formed on a substrate 100, a barrier 120 may be formed on the conductive layer 110, and a moderating layer 130 may be formed on the barrier 120. In some embodiments, a metal reactivity of the moderating layer 130 is less than a metal reactivity of the barrier 120 and a metal reactivity of the conductive layer 110. The layers 110, 120, and 130 may be formed by a deposition process, e.g., CVD, PVD, sputtering, or the like. The structure including the substrate 100 and the layers 110, 120, and 130 may be disposed in a precursor solution. In some embodiments, the precursor solution includes metal ions M4ⁿ⁺, and n is an integer from 1 to 3. The metal ions M4ⁿ⁺ may be silver ions (Ag⁺). In some embodiments, the metal reactivity of the metal M4 (e.g., Ag) of the precursor solution is greater than that of the moderating layer 130 and less than that of the conductive layer 110. In some embodiments, the conductive layer 110 includes Cu, the barrier 120 includes Ni, and the moderating layer 130 includes Au.

Referring to FIG. 5B, after the structure including the substrate 100 and the layers 110, 120, and 130 is disposed in the precursor solution, a replacement reaction may start to take place. In some embodiments, the metal M1 of the conductive layer 110 is oxidized to generate electrons and metal ions M1^{m+}, and m is an integer from 1 to 3 and the same as or different from n. The electrons may propagate toward the moderating layer 130, and the metal ions M1^{m+} may dissolve in the precursor solution. As the metal M1 of the conductive layer 110 is consumed to generate electrons and M1^{m+}, the volume of the conductive layer 110 is decreased. As shown in FIG. 5B, the sidewall 110s1 is recessed with respect to the sidewall 120s1 of the barrier 120 as the metal M1 is replaced. In some embodiments, the metal ions M1^{m+} generated from the moderating layer 130 may be copper ions (Cu²⁺).

Referring to FIG. 5C, the electrons generated from the moderating layer 130 may propagate toward the moderating layer 130 and react with the metal ions M4ⁿ⁺ of the precursor solution to form a layer of the metal M4 over the moderating layer 130. The metal ions M4ⁿ⁺ capture electrons and are reduced to form an electroless plating layer of the metal M4 on the moderating layer 130.

Referring to FIG. 5D, after a predetermined plating time has passed, a bonding layer 140 may be formed on the moderating layer 130, and the bonding layer 140 may be formed of the metal M4 by a replacement reaction of the metal M1. In some embodiments, the metal M1 is Cu, the metal M4 is Ag, and the replacement reaction taking place on the moderating layer 130 to form the bonding layer 140 may be represented by the following equation: Cu+2Ag⁺→Cu²⁺+2Ag. As such, the interconnection structure 1B is formed.

Table 2 shows experimental results of the distance D1, the thickness 140T, and the plating time of various embodiments E2-E6. In addition to the results shown in table 2, the bonding layer 140 formed by operations illustrated in FIGS. 5A-5D may include whisker-like metal nano-particles (e.g., the whisker-like metal nano-particles 140n illustrated in FIG. 1C), and free of a dendrite structure.

TABLE 2

| | E2 | | E3 | | E4 | | E5 | | E6 | |
|---|---|---|---|---|---|---|---|---|---|---|
| Plating time | 20 | seconds | 1 | minute | 3 | minutes | 5 | minutes | 100 | minutes |
| Thickness 140T | <0.1 | μm | 0.4 | μm | 0.8 | μm | 1.2 | μm | 8.7 | μm |
| Recessed distance D1 | 2.5 | μm | 5 | μm | 13 | μm | 21 | μm | 216 | μm |

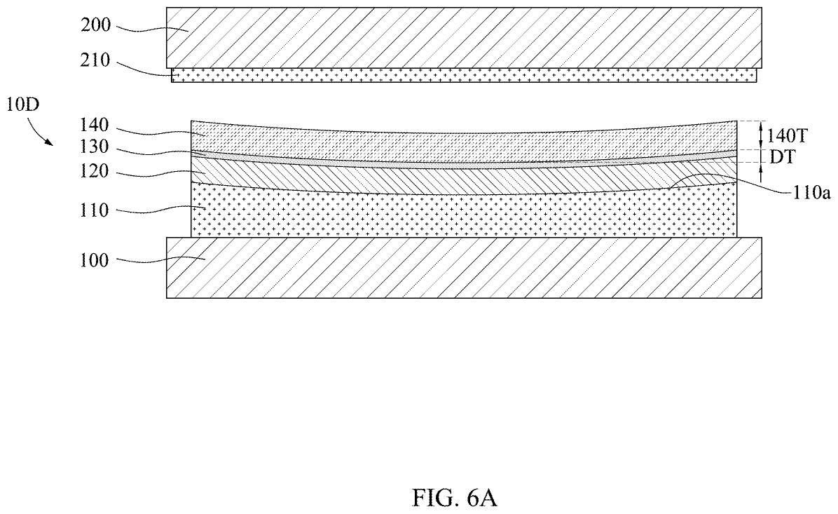

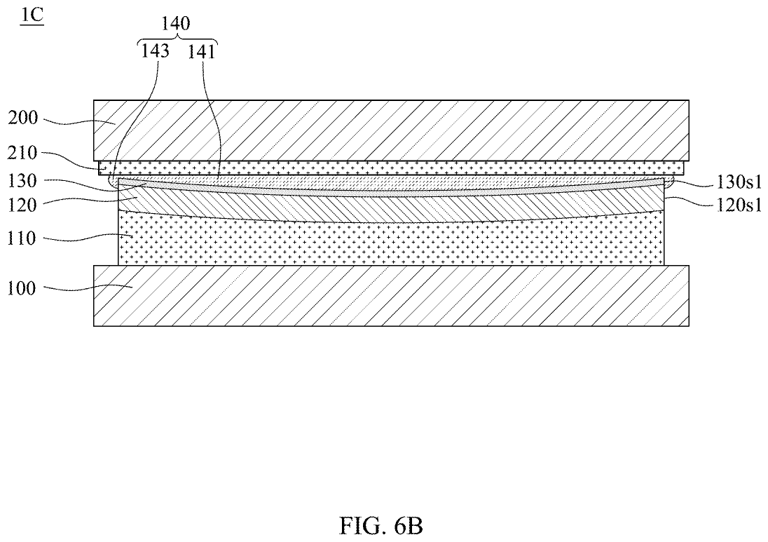

FIG. 6A and FIG. 6B illustrate various operations in a method of manufacturing a package structure 1C in accordance with some embodiments of the present disclosure.

Referring to FIG. 6A, an interconnection structure 10D may be provided over a substrate 100, and a conductive layer 210 may be formed on a substrate 200. In some embodiments, the interconnection structure 10D may be formed by forming a conductive layer 110 on the substrate 100, performing a polishing operation (e.g., CMP) on the conductive layer 110 to form a curved top surface 110a concave toward a center or an inside of the conductive layer 110, and conformally forming the layers 120 and 130 and the bonding layer 140 on the curved top surface 110a of the conductive layer 110. The bonding layer 140 may be formed by operations similar to those illustrated in FIGS. 5A-5D. The bonding layer 140 may include whisker-like metal nano-particles (e.g., the whisker-like metal nano-particles 140n illustrated in FIG. 1C). The bonding layer 140 is relatively soft compared to the conductive layers 110 and 210. In some embodiments, the thickness 140T of the bonding layer 140 is equal to or greater than about 0.8 μm. In some embodiments, the thickness 140T of the bonding layer 140 is greater than a recessed depth DT (also referred to as “a dishing depth”) of the top surface 130a of the moderating layer 130. In some embodiments, a sintering temperature of the bonding layer 140 is lower than a melting temperature of the bonding layer 140.

Referring to FIG. 6B, the conductive layer 210 may be connected to the bonding layer 140 by a thermal bonding process. After the conductive layer 210 is pressed against the bonding layer 140 under a sintering temperature (e.g., about 200° C. for the bonding layer 140 including Ag nano-particles) that is lower than a melting temperature of the bonding layer 140 (e.g., about 960° C. for Ag), the bonding layer 140 is softened, and a portion 143 of the softened bonding layer 140 is squeezed out of the space between the conductive layers 110 and 210. As a result, the thickness 140T of the bonding layer 140 after the thermal bonding process is reduced compared to that before the thermal bonding process. In some embodiments, the difference in the thickness 140T of the bonding layer 140 between prior to and after the bonding operation may be up to about 450 nm, about 475 nm, or about 500 nm. For example, the thickness 140T may be reduced from about 560 nm to about 85 nm after the bonding operation. As such, the package structure 1C is formed.

According to some embodiments of the present disclosure, with the design of the original thickness 140T of the bonding layer 140 being greater than the recessed depth DT (or the dishing depth) of the top surface 130a of the moderating layer 130, the dishing or curved top surface 130a of the moderating layer 130 may be completed filled by the bonding layer 140, and there is no void or air gap between the bonding layer 140 and the conductive layer 210. Accordingly, the bonding strength is improved.

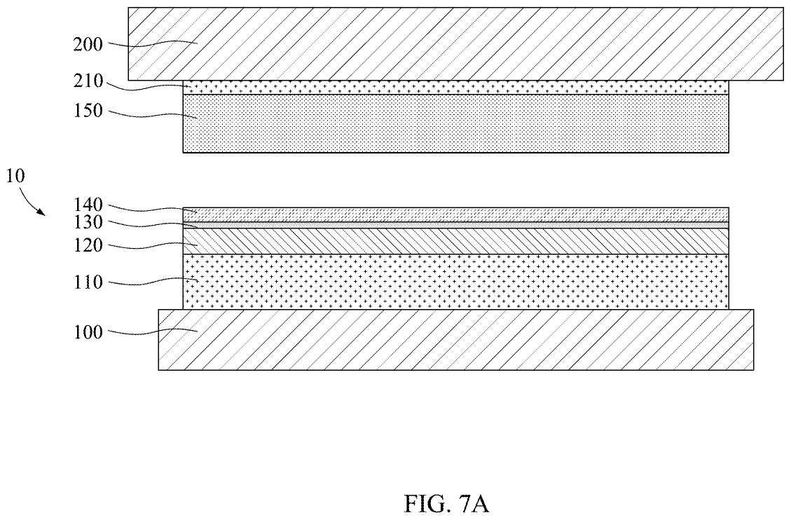

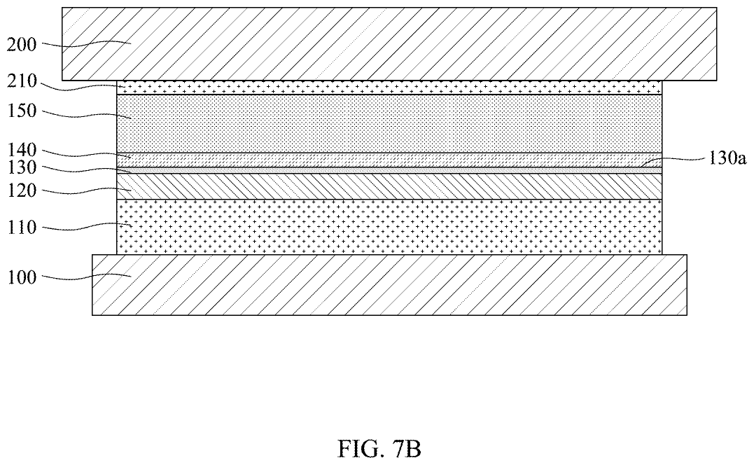

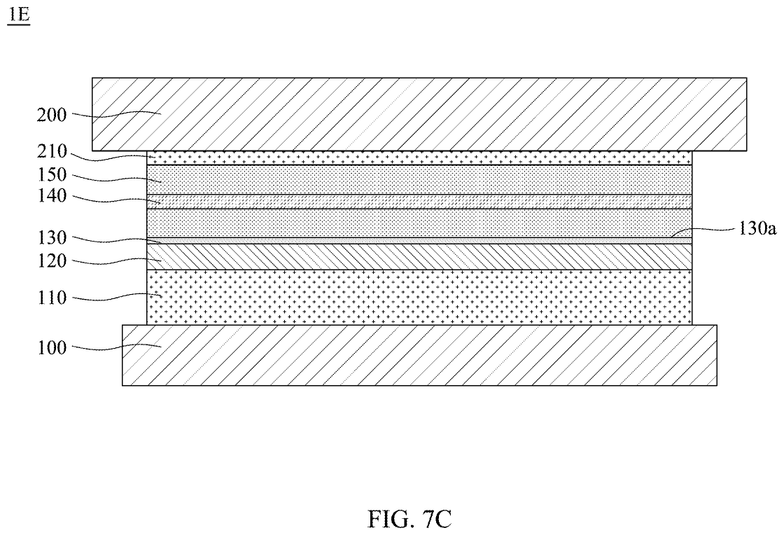

FIG. 7A, FIG. 7B, and FIG. 7C illustrate various operations in a method of manufacturing a package structure 1E in accordance with some embodiments of the present disclosure.

Referring to FIG. 7A, an interconnection structure 10 may be provided over a substrate 100, a conductive layer 210 may be formed on a substrate 200, and a bonding layer 150 may be formed on the conductive layer 210. In some embodiments, the interconnection structure 10 may be formed by forming the layers 110, 120 and 130 and the bonding layer 140 on the substrate 100. The bonding layer 140 may be formed by operations similar to those illustrated in FIGS. 5A-5D. The bonding layer 140 may include whisker-like metal nano-particles (e.g., the whisker-like metal nano-particles 140n illustrated in FIG. 1C). The bonding layer 150 may include a soldering material. For example, the bonding layer 150 may include Sn.

Referring to FIG. 7B, the conductive layer 210 may be connected to the conductive layer 110 through the bonding layer 140 and the bonding layer 150 by a thermal bonding process. In some embodiments, a melting temperature of the bonding layer 140 (e.g., about 960° C. for Ag) is greater than a melting temperature of the bonding layer 150 (e.g., about 232° C. for SnAg). In some embodiments, a sintering temperature of the bonding layer 140 (e.g., about 200° C. for the bonding layer 140 including Ag nano-particles) is lower than the melting temperature of the bonding layer 150 (e.g., about 232° C. for SnAg). In some embodiments, the bonding layer 150 has a metal reactivity less than that of the bonding layer 140.

Referring to FIG. 7C, after the bonding layer 150 is pressed against the bonding layer 140 under a sintering temperature that is lower than a melting temperature of the bonding layer 140, the bonding layer 140 may start to diffuse in a direction away from the surface 130a of the moderating layer 130. The bonding layer 140 may diffuse within the bonding layer 150, and the bonding layer 150 may connect to the moderating layer 130. In some embodiments, with the design of the metal reactivity of the bonding layer 140 being less than that of the conductive layer 110 and/or the metal reactivity of the bonding layer 140 being greater than that of the moderating layer 130, the bonding layer 140 diffuses toward the bonding layer 150 rather than toward the conductive layer 110. As a result, the bonding layer 150 may be bonded to the conductive layer 110 and/or the moderating layer 130 under a sintering temperature that is lower than a melting temperature of the bonding layer 140. As such, the package structure 1E is formed.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of said numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations do not limit the present disclosure. It can be clearly understood by those skilled in the art that various changes may be made, and equivalent components may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and the like. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. An interconnection structure, comprising:
a substrate;
a conductive layer over the substrate and having a top surface;
a bonding layer over the top surface of the conductive layer; and
a moderating layer between the conductive layer and the bonding layer and configured to mitigate an increase in a surface roughness of the top surface of the conductive layer during an electroless plating process for forming the bonding layer.

2. The interconnection structure as claimed in claim 1, wherein a metal reactivity of the bonding layer is less than a metal reactivity of the conductive layer.

3. The interconnection structure as claimed in claim 2, further comprising a barrier between the conductive layer and the moderating layer, wherein the metal reactivity of the bonding layer is less than a metal reactivity of the barrier.

4. The interconnection structure as claimed in claim 3, wherein the metal reactivity of the bonding layer is greater than a metal reactivity of the moderating layer.

5. The interconnection structure as claimed in claim 1, wherein a width of the conductive layer is less than a width of the moderating layer.

6. The interconnection structure as claimed in claim 5, wherein the width of the conductive layer is less than a width of the bonding layer.

7. The interconnection structure as claimed in claim 6, wherein a sidewall of the conductive layer comprises a curved surface concave toward a center of the conductive layer.

8. The interconnection structure as claimed in claim 5, wherein a surface roughness of a sidewall of the conductive layer is greater than a surface roughness of a surface of the bonding layer.

9. The interconnection structure as claimed in claim 3, wherein a width of the conductive layer is less than a width of the barrier.

10. The interconnection structure as claimed in claim 3, wherein a portion of a bottom surface of the barrier is concave toward a center of the barrier.

11. The interconnection structure as claimed in claim 1, wherein the bonding layer has a curved bottom surface convex toward the moderating layer.

12. The interconnection structure as claimed in claim 1, wherein the bonding layer comprises a plurality of whisker-like nano-particles.

13. A package structure, comprising:
a first conductive structure;
a second conductive structure facing the first conductive structure; and
an electroless bonding layer connecting the first conductive structure to the second conductive structure, wherein the electroless bonding layer covers a portion of a lateral surface of the first conductive structure.

14. The package structure as claimed in claim 13, wherein the electroless bonding layer comprises a central portion and a peripheral portion adjacent to the central portion, and a thickness of the central portion is greater than a thickness of the peripheral portion.

15. The package structure as claimed in claim 13, wherein the electroless bonding layer has a curved bottom surface concave towards the first conductive structure and a substantially flat top surface opposite to the curved bottom surface.

16. The package structure as claimed in claim 13, wherein the first conductive structure comprises an intermediate metal layer, and the electroless bonding layer contacts a top surface and a lateral surface of the intermediate metal layer.

17. The package structure as claimed in claim 13, wherein the first conductive structure comprises an intermediate metal layer, and the electroless bonding layer comprises:
a first portion between the second conductive structure and a top surface of the intermediate metal layer; and
a second portion protruded from a lateral surface of the intermediate metal layer.

18. The package structure as claimed in claim 17, wherein the first conductive structure further comprises a barrier, the intermediate metal layer is between the barrier and the electroless bonding layer, and the second portion of the electroless bonding layer further contacts the barrier.

19. The package structure as claimed in claim 13, wherein the electroless bonding layer is configured to bond the first conductive structure with the second conductive structure at a temperature lower than a melting temperature of the electroless bonding layer.

20. The package structure as claimed in claim 13, the electroless bonding layer comprises a plurality of nano-particles, and a sintering temperature of the plurality of nano-particles is lower than a melting temperature of the plurality of nano-particles.
